(19) United States
(12) Patent Application Publication
(10) Pub. No.: US 2007/0009658 A1
(43) Pub. Date: Jan. 11, 2007

(54) Pulse nucleation enhanced nucleation technique for improved step coverage and better gap fill for WCVD process

(76) Inventors: Jong Hyun Yoo, Milpitas, CA (US); Xinliang Lu, Sunnyvale, CA (US); Chiliang Chen, Sunnyvale, CA (US); Ken Kaung Lai, Milpitas, CA (US); Chien-Teh Kao, Sunnyvale, CA (US)

Correspondence Address: PATTERSON & SHERIDAN, LLP, 3040 POST OAK BOULEVARD, SUITE 1500, HOUSTON, TX, 77056, US

(21) Appl. No.: 10/023,125

(22) Filed: Dec. 17, 2001

Related U.S. Application Data
(60) Provisional application No. 60/305,307, filed on Jul. 13, 2001.

(51) Int. Cl. C23C 16/00

(52) U.S. Cl. 427/248.1; 118/715; 118/697

(57) ABSTRACT

A process and an apparatus is disclosed for forming refractory metal layers employing pulse nucleation to minimize formation of a concentration boundary layer during nucleation. The surface of a substrate is nucleated in several steps. Following each nucleation step is a removal step in which all reactants and by-products of the nucleation process are removed from the processing chamber. Removal may be done by either rapidly evacuating the processing chamber, rapidly introducing a purge gas therein or both. After removal of the process gas and by-products from the processing chamber, additional nucleation steps may be commenced to obtain a nucleation layer of desired thickness. After formation of the nucleation layer, a layer is formed adjacent to the nucleation layer using standard bulk deposition techniques.

### CROSS-REFERENCE TO RELATED PATENT APPLICATIONS

The present application claims priority from United States provisional patent application number 60/305,307, filed Jul. 13, 2001 and entitled PULSE NUCLEATION ENHANCED NUCLEATION TECHNIQUE FOR IMPROVED STEP COVERAGE AND BETTER GAP FILL FOR WCVD PROCESS, which is incorporated by reference herein.

### BACKGROUND OF THE DISCLOSURE

This invention relates to the processing of semiconductor substrates. More particularly, this invention relates to improvements in the process of depositing metal layers on semiconductor substrates.

The semiconductor processing industry continues to strive for larger production yields while increasing the uniformity of layers deposited on substrates with larger surface areas. These same factors, in combination with new materials, also provide higher integration of circuits per unit area of the substrate. As circuit integration increases, the need for greater uniformity and process control regarding the physical and electrical properties of deposited metal layers is desired. To that end, nucleation of a substrate with material prior to layer formation has proved particularly beneficial.

Nonetheless, improved nucleation techniques to deposit metal layers are desirable.

### SUMMARY OF THE INVENTION

The present invention provides a process and apparatus for forming an improved metal film by nucleating the substrate with tungsten while minimizing formation of a concentration boundary layer by implementing a multi-step nucleation technique. The method includes depositing a tungsten film on a substrate disposed in a processing chamber comprises heating the substrate; and introducing into, and removing from, the processing chamber, a process gas consisting of a tungsten source and a hydrogen source to nucleate the substrate with tungsten while controlling production of a concentration boundary layer by rapidly removing the process gas from the processing chamber after commencement of nucleation of the substrate. One exemplary embodiment of the process includes nucleating the substrate with tungsten by systematically introducing, for less than about 7 seconds, a process gas into the processing chamber, and removing the process gas from the processing chamber. To that end, the process gas includes a tungsten source and a silicon source. The processing chamber is pressurized to a first pressure level in the range of 2-30 Torr upon introduction of the process gas and is pressurized to a second pressure level that is lower than the first pressure level upon removal of the process gas.

### BRIEF DESCRIPTION OF THE DRAWINGS

FIG. 1 is a vertical cross-sectional view of one embodiment of a simplified chemical vapor deposition (CVD) system according to one embodiment of the present invention;

FIG. 2 is a vertical cross-sectional view of one embodiment of a resistively heated susceptor used in the processing chamber of FIG. 1 to secure a substrate disposed therein;

FIG. 3 is a simplified plan view showing the connection of gas supplies to the CVD system shown above in FIG. 1;

FIG. 4 is a detailed cross-sectional view of a substrate shown above in FIG. 1 before nucleation of the substrate with a refractory metal layer;

FIG. 5 is a detailed cross-sectional view of the substrate shown above in FIG. 4 after nucleation and bulk deposition of the refractory metal layer, in accordance with one embodiment of the present invention;

FIG. 6 is a detailed cross-sectional view of the substrate showing deleterious effects of nucleation in accordance with prior art nucleation techniques;

FIG. 7 is a detailed cross-sectional view of a substrate shown above in FIG. 1 demonstrating the creation of a concentration boundary layer during nucleation of the substrate with a refractory metal layer;

FIG. 8 is a graph showing by-product concentration in the processing chamber shown in FIG. 1, versus time during nucleation of a substrate with a refractory metal layer in accordance with the present invention;

FIG. 9 is a graph showing the thickness of a concentration boundary layer versus the time required for removing a process gas and by-products from a processing chamber, in accordance with the present invention;

FIG. 10 is a graph showing deposition rate of a refractory metal nucleation layer on a substrate versus the time required for removing a process gas and by-products from a processing chamber, in accordance with the present invention;

FIG. 11 is a flowchart illustrating the process for depositing the refractory metal layer shown in FIG. 5, in accordance with one embodiment of the present invention;

FIG. 12 is a flowchart illustrating the process for depositing the refractory metal layer shown in FIG. 5, in accordance with a first alternate embodiment of the present invention;

FIG. 13 is a flowchart illustrating the process for depositing the refractory metal layer shown in FIG. 5, in accordance with a second alternate embodiment of the present invention;

FIG. 14 is a simplified diagram of system monitors used in association with the CVD system shown above in FIGS. 1-3, in a multi-chamber system; and

FIG. 15 shows an illustrative block diagram of the hierarchical control structure of the system control software employed to control the system shown above in FIG. 1.

### DETAILED DESCRIPTION OF THE PREFERRED EMBODIMENTS

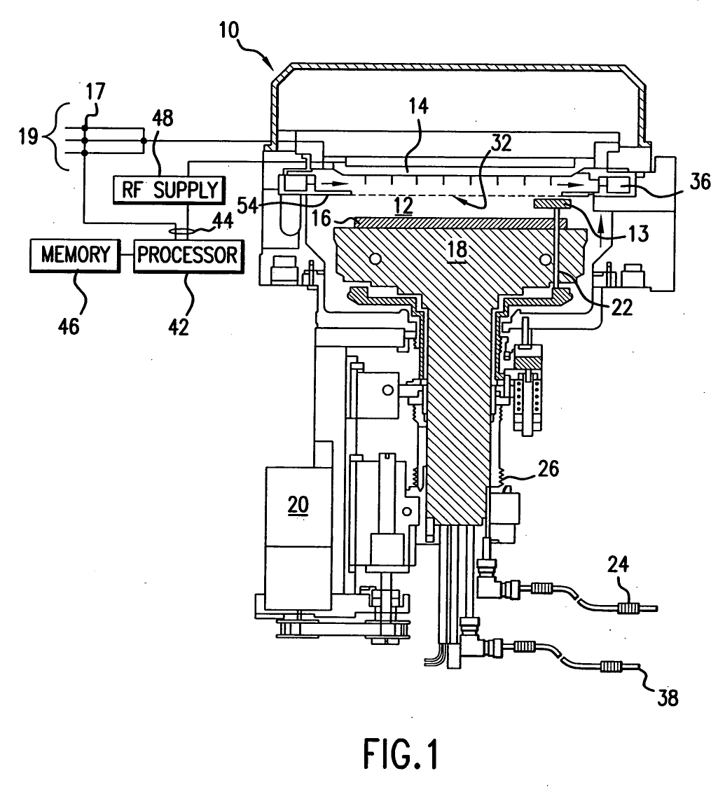

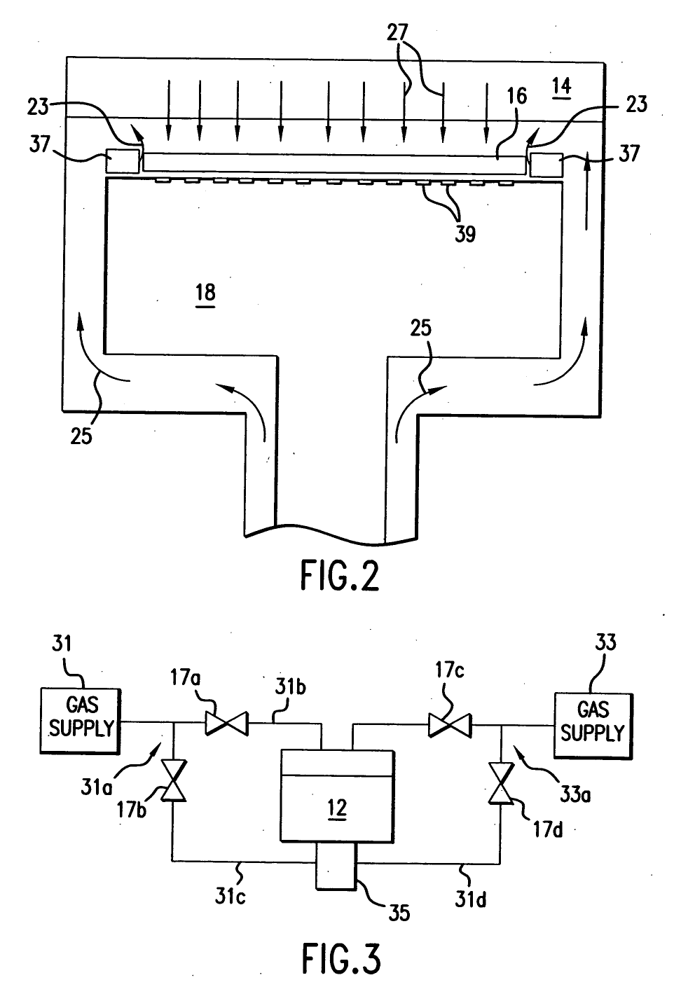

Referring to FIGS. 1 and 2, an exemplary processing system 10 is shown employed to deposit a refractory metal film, in accordance with one embodiment of the present invention. System 10 is a parallel plate, cold-wall, chemical vapor deposition (CVD) system. CVD system 10 has a processing chamber 12. Disposed within processing chamber 12 is a gas distribution manifold 14. Gas distribution manifold 14 disperses deposition gases passing into processing chamber 12, with the deposition gases impinging upon a wafer 16 that rests on a resistively-heated susceptor 18.

Processing chamber 12 may be part of a vacuum processing system having multiple processing chambers connected to a central transfer chamber (not shown) and serviced by a robot (not shown). Substrate 16 is brought into processing chamber 12 by a robot blade (not shown) through a slit valve (not shown) in a sidewall of processing chamber 12. Susceptor 18 is moveable vertically by means of a motor 20. Substrate 16 is brought into processing chamber 12 when susceptor 18 is in a first position 13 opposite the slit valve (not shown). At position 13, substrate 16 is supported initially by a set of pins 22 that pass through susceptor 18. Pins 22 are driven by a single motor assembly 20.

As susceptor 18 is brought to a processing position 32, located opposite gas distribution manifold 14, pins 22 retract into susceptor 18, to allow substrate 16 to rest on susceptor 18. Once positioned on susceptor 18, substrate 16 is affixed to the susceptor by a vacuum clamping system shown as grooves 39.

As it moves upward toward processing position 32, substrate 16 contacts purge guide 37, which centers substrate 16 on susceptor 18. Edge purge gas 23 is flowed through purge guide 37, across the edge of substrate 16 to prevent deposition gases from coming into contact with the edge and backside of substrate 16. Purge gas 25 is also flowed around susceptor 18 to minimize deposition on or proximate to the same. These purge gases are supplied from a purge line 24 and are also employed to protect stainless steel bellows 26 from damage by corrosive gases introduced into processing chamber 12 during processing.

Referring to FIGS. 1 and 3, deposition and carrier gases are supplied to a deposition zone of processing chamber 12, through gas lines 19, to manifold 14 in response to the control of valves 17. To that end, provided are gas supplies 31 and 33 that are selectively placed in fluid communication with processing chamber 12 by valves 17. Specifically, valves 17 include valves 17a, 17b, 17c and 17d. A feedline 31a places gas supply 31 in fluid communication with valves 17a and 17b. A feedline 31b places valve 17a in fluid communication with processing chamber 12. A feedline 31c places valve 17b in fluid communication with foreline 35. Feedline 33a places gas supply 31 in fluid communication with valves 17c and 17d. Feedline 33b places valve 17c in fluid communication with processing chamber 12. Feedline 33c places valve 17d in fluid communication with foreline 35. Activation of valve 17a allows process gas from gas supply 31 to enter processing chamber 12. Activation of valve 17c allows process gas from gas supply 33 to enter processing chamber 12. Activation of valve 17b allows process gas from gas supply 31 to enter foreline 35, and activation of valve 17d allows process gas from gas supply 31 to enter processing chamber 12.

Referring again to FIGS. 1 and 2, during processing, gas supplied to manifold 14 is distributed uniformly across the surface of substrate 16, as shown by arrow 27. Spent processing gases and by-product gases are exhausted from processing chamber 12 by means of an exhaust system 36. The rate at which gases are released through exhaust system 36 into an exhaust line is controlled by a throttle valve (not shown). During deposition, a second purge gas is introduced through gas channels (not shown) present in susceptor 18. Feedline 38 directs the purge gas against the edge of substrate 16, as previously described. An RF power supply 48 can be-coupled to manifold 14 to provide for plasma-enhanced CVD (PECVD) or cleaning of processing chamber 12.

The throttle valve (not shown), gas supply valves 17, motor 20, resistive heater coupled to susceptor 18, RF power supply 48, and other aspects of CVD system 10 are operated under control of a processor 42 over control lines 44 (only some of which are shown). Processor 42 operates on a computer program stored in a computer-readable medium such as a memory 46. System controller 42 controls all of the activities of the CVD machine. The computer program includes sets of instructions that dictate the timing, mixture of gases, chamber pressure, chamber temperature, RF power levels, susceptor position, and other parameters of a particular process and is discussed more fully below. Processor 42 may also operate other computer programs stored on other memory devices including, for example, a floppy disk or other another appropriate drive.

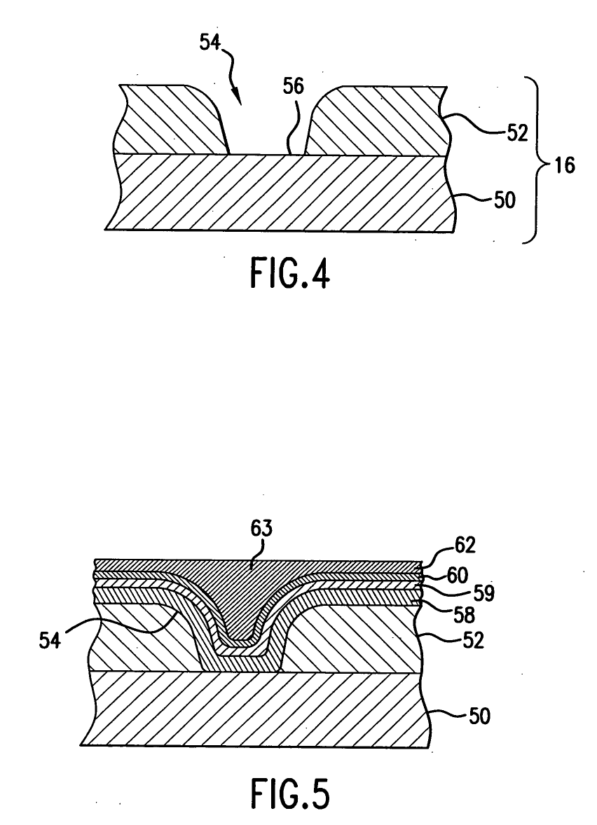

Referring to FIGS. 1 and 4, an exemplary use for system 10 is to deposit refractory metal layers on substrate 16 employing a nucleation technique to nucleate substrate 16 with a refractory metal layer. To that end, substrate 16 includes a wafer 50 having one or more layers, shown as layer 52 present. Alternatively, no layers may be present on wafer 50. Wafer 50 may be formed from any material suitable for semiconductor processing, such as silicon. Layers 52 may be formed from any suitable material, including dielectric or conductive materials. Layer 52 may include a void 54, exposing a region 56 of substrate 16, or a layer 58, such as a titanium nitride layer, disposed between layer 52 and wafer 50, shown more clearly in FIG. 5.

Referring to FIG. 5, an example of a refractory metal layer deposited in accordance with one embodiment is a tungsten layer employed to form a contact adjacent to a barrier layer 58 formed from titanium nitride, TiN. Disposed between layer 52 and layer 58 is an adhesion layer 59 formed from Titanium, Ti. Layers 58 and 59 conform to the profile of the void 54, covering region 56 and layer 52. Adjacent to layer 58 is a nucleation layer 60 that is formed from tungsten, as discussed further below. Layer 60 conforms to the profile of layers 58 and 59, and therefore, conforms to the profile of void 54. Formed adjacent to the nucleation layer is a bulk deposition layer 62 of tungsten. In this example, bulk deposition layer 62 is employed to form a contact. Nucleation layer 60 serves to improve the step coverage of the resulting bulk deposition layer 62, and therefore, the resistivity of resulting contact 63.

Difficulty arises when depositing nucleation layer 60. Specifically, as the aspect ratio of void 54 increases, so does the difficulty in producing a nucleation layer having uniform thickness and acceptable conformableness.

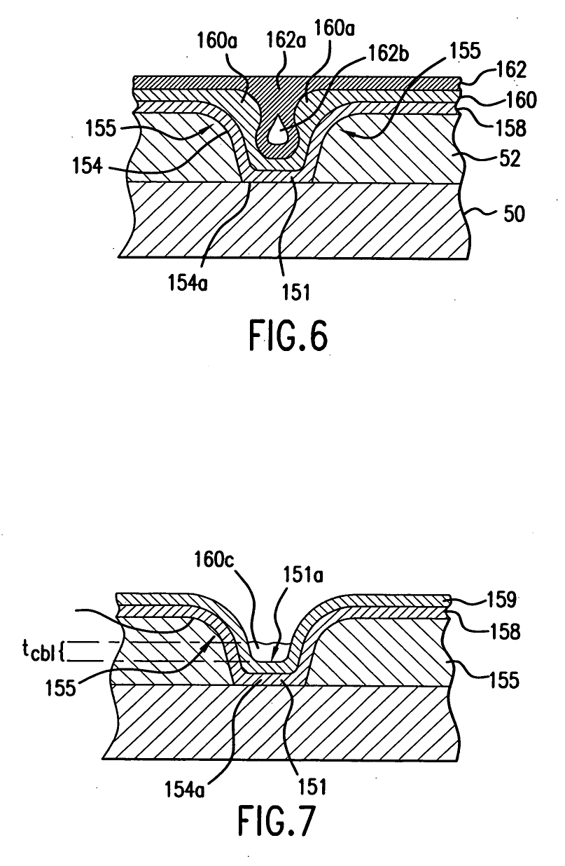

Referring to FIGS. 6 and 7, in an extreme case, pinch-off occurs that is shown in region 162a that is adjacent to upper areas 155 of void 154. Pinch-off leaves a void 162b and results from a re-entrant profile of nucleation layer 160. It is believed that the re-entrant profile of nucleation layer 160 results from a concentration of gaseous material referred to herein as a concentration boundary layer (CBL) 160c that forms proximate to nadir 154a. It is believed that CBL 160c results from reactions between the region 151 adjacent to nucleation layer 160, which in this example is the portion of layer 159 positioned proximate to nadir 154a, and the by-products of the reactants resulting from formation of nucleation layer 160. Specifically, the byproducts of the reaction and outgassing from region 151 forms a gaseous material that provides CBL 160c with a thickness t_{CBL}. The thickness t_{CBL} increases the distance, also referred to as diffusion length, which the precursors must travel before reaching the region in void 154 upon which nucleation is to occur that is furthest from upper areas 155. In the present example the region that is furthest from upper areas 155 upon which nucleation it to occur is surface 151a disposed proximate to nadir 154a. This increased diffusion length results in an increase in the time required to deposit nucleation layer 160 on this region, compared to the nucleation time for deposition on other regions within void 154, such as upper regions 155. As a result, nucleation layer 160 deposits much more rapidly in regions proximate to upper areas 155 than the surface 151a that is proximate to nadir 154a.

Referring to FIGS. 5 and 7, an exemplary process in which the drawbacks of CBL 160c are overcome with the present invention involves the deposition of a refractory metal layer, such as a tungsten layer. To that end, nucleation of substrate 16 is undertaken with tungsten-hexafluoride WF₆ being employed as a tungsten source and either molecular hydrogen, H₂, silane, SiH₄, or diborane, B₂H₆, being employed as a hydrogen source. The nucleation is defined by the following reaction equations:
WF₆+H₂→HF+W+H₂ (1)
WF₆+SiH₄→HF+W+SiH₄+SiFₓ (2)
WF₆+B₂H₆→HF+W+BₓF_{y}+BₓH_{y} (3)
Nucleation layer 60 is formed from W on the right hand side of the reaction equations 1, 2 and 3, with HF and being one of the resulting byproducts from each of these reactions. Reaction 1 also has a reaction by product that includes H₂, which results from a hydrogen-rich environment. Reaction 2 also includes SiFₓ and silane as additional byproducts, and equation 3 includes byproducts of BₓF_{y}, BₓH_{y.} It is the aforementioned by-products, coupled with outgassing from region 151 and reactions that occur from impurities in region 151 that produces gas-phase CBL 160c.

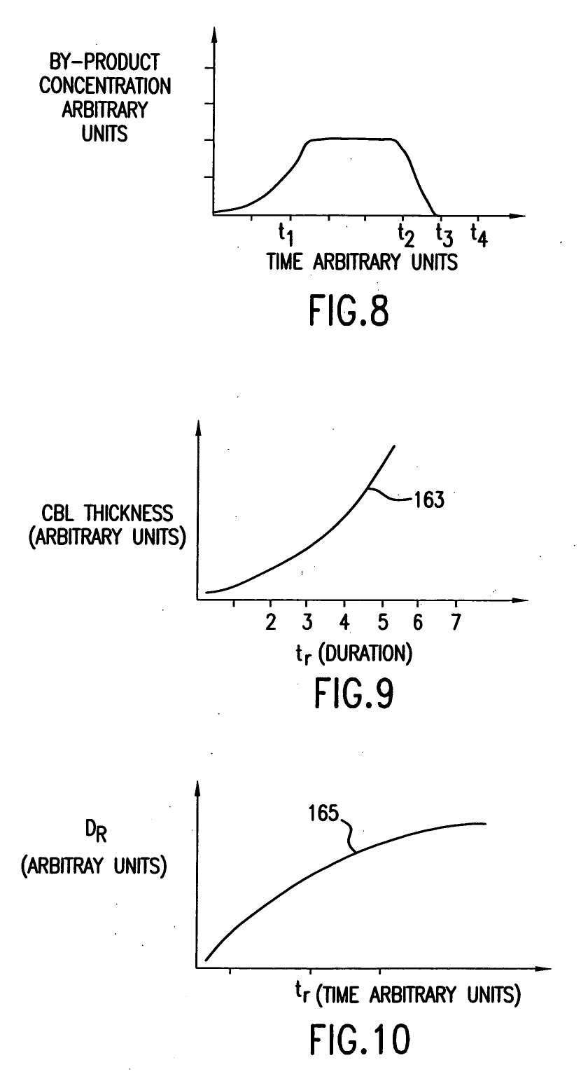

Referring to FIGS. 1, 7 and 8, to reduce, if not avoid, the problems presented by CBL 160c, the by-products of the deposition process and gases present are periodically removed from processing chamber 12 during nucleation. Specifically, at time ti, the process gases are first introduced into processing chamber 12. As time progresses, formation of nucleation layer 160 continues that results in increased concentration of by-products and increased quantities of material outgassed from region 151. At time t₂, the introduction of process gases into processing chamber 12 is terminated. Thus, between time t, and t₂, nucleation occurs, referred to as nucleation time tₙ. Concurrent with termination of the flow of process gas into processing chamber 12 at time t₂, removal of the same is effectuated. This may be achieved by introducing an inert purge gas, such as Ar or N₂, or by rapidly depressurizing processing chamber 12 or both. The desired result, however, is that by time t₃, process gases and by-products and material outgassed from region 151, which attribute to the formation of CBL 160c, are removed from processing chamber 12. The time interval between t₂ and t₃ is referred to as removal time tᵣ. At time t₃, processing chamber 12 is once again pressurized and the process gas introduced at time t₄ to continue nucleation of substrate.

It was discovered that for a given nucleation time tₙ, the deposition rate, D_{R}, layer thickness, as well as uniformity and conformability of nucleation layer 60 may be controlled as a function of removal time t_{r.} Specifically, the shorter the duration of tᵣ, the greater the improvement of thickness uniformity and conformability of nucleation layer 60 due to a reduction of the CBL, shown by curve 163 in FIG. 9. However, the shorter the duration of removal time tᵣ, the greater the deposition time required to achieve nucleation, shown by curve 165 in FIG. 10. Therefore, for a given nucleation time, t_{r,} the removal time, t_{r,} may be optimized to achieve maximum deposition rate while maximizing the thickness uniformity and conformableness of a nucleation layer. The optimized duration for the removal time, t_{r,} is dependent upon many factors, such as the aspect ratio of void 154, shown in FIG. 5, the deposition chemistry, the process parameters and the like.

An exemplary process for nucleating a substrate that takes the advantages of the principles set forth above into account, is described with respect to FIGS. 1, 8 and 11, and the deposition of a tungsten layer. The instructions to carryout the process to deposit a tungsten layer on substrate 16 are stored as a computer-readable program in memory 46, which is operated on by processor 42 to place substrate 16 in processing position 32, at step 300. At step 302, substrate 16 is heated to an appropriate temperature. In the present embodiment, substrate 16 is heated to approximately 400° C., but the desired temperature may be in the range of 200 to 600° C. At step 304, the chamber pressure is set to an initial pressure level of approximately 90 Torr, but may be in the range of 70 to 120 Torr. A hydrogen-containing gas, for example, silane, SiH₄, is then introduced into processing chamber 12, so that substrate 16 may soak in the same at step 306. The soak time for substrate 16 is approximately 15 seconds. However, the range of time over which substrate 16 soaks in silane may be in the range of 10 to 30 seconds. To that end, silane is introduced into processing chamber 12 with an inert carrier gas, such as Argon, Ar, with the flow rate of Ar being approximately ten times greater than the rate at which silane is introduced. In one example, Ar is introduced at a rate of approximately 1,000 standard cubic centimeters per second (sccm) and silane at a rate of approximately 100 sccm.

At step 308, the flow chamber pressure is established to be approximately 15 Torr and may be in the range of 2 to 30 Torr. Carrier gases are flowed into processing chamber 12 at step 310. Although any carrier gas may be employed, one example employs Ar and molecular hydrogen, H₂, each of which is introduced into processing chamber 12 at a rate in the range of 2000 to 6000 sccm, with 4000 sccm being an exemplary rate. The carrier gases Ar and H₂ are introduced for approximately 10 seconds. However, the duration in which carrier gases are introduced into processing chamber 12 may range from 5 to 15 seconds.

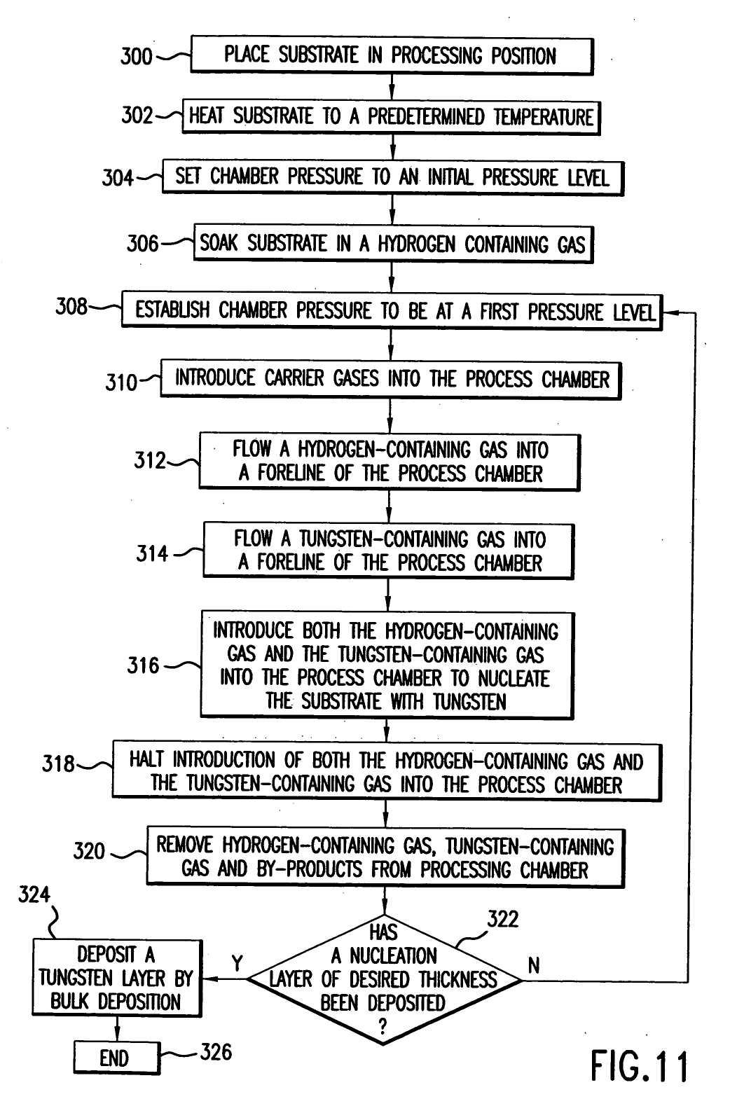

Referring to both FIGS. 3 and 11, at step 312 a hydrogen-containing gas is flowed into foreline 35, and at step 314 a tungsten-containing gas is flowed into foreline 35. The rate at which gases are flowed into foreline 35 is regulated to create a mixture of hydrogen-containing gas and tungsten-containing gas in order to achieve a ratio of tungsten-containing gas to hydrogen-containing gas in the range of 1:1 to 5:1. In one example, the hydrogen-containing gas that is employed is silane, SiH₄, and the tungsten-containing gas that is employed is tungsten-hexafluoride, WF₆. Silane is flowed at a rate of 20 sccm and the tungsten-hexafluoride is flowed in at a rate of 40 sccm, for approximately 5 seconds. To that end, gas supply 31 includes SiH₄ with an H₂ carrier gas, and supply 33 includes WF₆ with an Ar carrier gas. The mixture of SiH₄ and WF₆ is flowed into foreline 35 before being diverted into processing chamber 12, in order to avoid pressure spikes that may cause particulate contamination. Specifically, the flow of SiH₄ and WF₆ is stabilized in foreline 35, after which the SiH₄ and WF₆ mixture is introduced into processing chamber 12.

Referring again to FIGS. 1 and 11, at step 316, the mixture of SiH₄ and WF₆ is flowed into processing chamber 12 to nucleate substrate 16 with tungsten. The nucleation is carried-out for sufficient time to start nucleation of layer 160. The nucleation time is typically in the range of 1 to several seconds and is typically approximately 3 seconds. At step 318, the introduction of the mixture of SiH₄ and WF₆ into processing chamber 12 is halted before t_{CBL} has reached a level to substantially hinder nucleation. At step 320, the mixture of SiH₄ and WF₆ is removed from processing chamber 12, along with the gaseous by-products of the reaction of the SiH₄-WF₆ nucleation. Removal of these gases may be achieved by reducing the chamber pressure, introducing a purge gases therein, while maintaining chamber pressure or both. Typically the removal step lasts 3-12 seconds. Exemplary purge gases may be any inert gas such as Ar or N₂. The present exemplary method, however, removes the mixture of SiH₄ and WF₆ as well as the gaseous by-products of the reaction of the SiH₄-WF₆ nucleation by reducing the chamber pressure to be in the range of approximately 1 to 3 Torr.

Referring to FIGS. 1, 5 and 11, at step 322, it is determined whether nucleation layer 60 is of sufficient, or desired, thickness. This determination may be achieved using any know process in the semiconductor art. For example, a spectroscopic measurement of the nucleation layer may be made. Alternatively, the thickness of nucleation layer 60 may be calculated, i.e., modeled, employing the known flow rates and other operational characteristics of system 10 and the deposition process. Were the desired thickness of nucleation layer 60 achieved, then the process would proceed to step 324 where a bulk deposition would occur to deposit tungsten layer 62 adjacent to nucleation layer 60 using conventional CVD techniques. After deposition of the bulk tungsten layer 62, the process ends at step 326. It should be understood that the nucleation may occur in a common chamber, two different chambers or a common mainframe or two different chambers of differing mainframes.

Were it determined, at step 320, that the nucleation layer was not of desired thickness, then the process proceeds to step 308 and repeats steps 308, 310, 312, 314, 316, 318, 320 and 322, until nucleation layer 60 obtains the desired thickness. In this manner, nucleation of substrate 16 is achieved employing multiple steps, namely, a pulse nucleation technique. The nucleating gases are pulsed into processing chamber 12 for a few seconds and quickly removed by the rapid depressurization of processing chamber 12 or introduction of purge gases. This step lasts approximately 3 to 12 seconds. It is believed that the pulse nucleation technique reduces formation of a concentration boundary layer that results from outgassing when the surface is being nucleated. Specifically, it is believed that a diffusive flux of reactants employed to nucleate the surface may substantially reduce the aforementioned outgassing. The deleterious impact of the concentration boundary layer is found to be reduced with the present process. In the present process, the concentration boundary layer is allowed to form as large a size as possible while still maintaining suitable diffusive flux of reactants employed to nucleate the surface underlying the concentration boundary layer. Thereafter, all of the process gases, reaction by-products and the material that forms the concentration boundary layer are removed from processing chamber 12 by rapidly depressurizing the same or introducing purge gases therein. This process is repeated until nucleation layer 60 reaches a suitable thickness.

Referring to FIG. 7, an alternate process for forming a tungsten layer to enhance step coverage is shown. For example, by adjusting the ratio of the tungsten-containing gas to the hydrogen-containing gas to be much lower during the initial stages of nucleation, the amount of fluorine present to diffuse in region 151 is reduced. This improves step coverage.

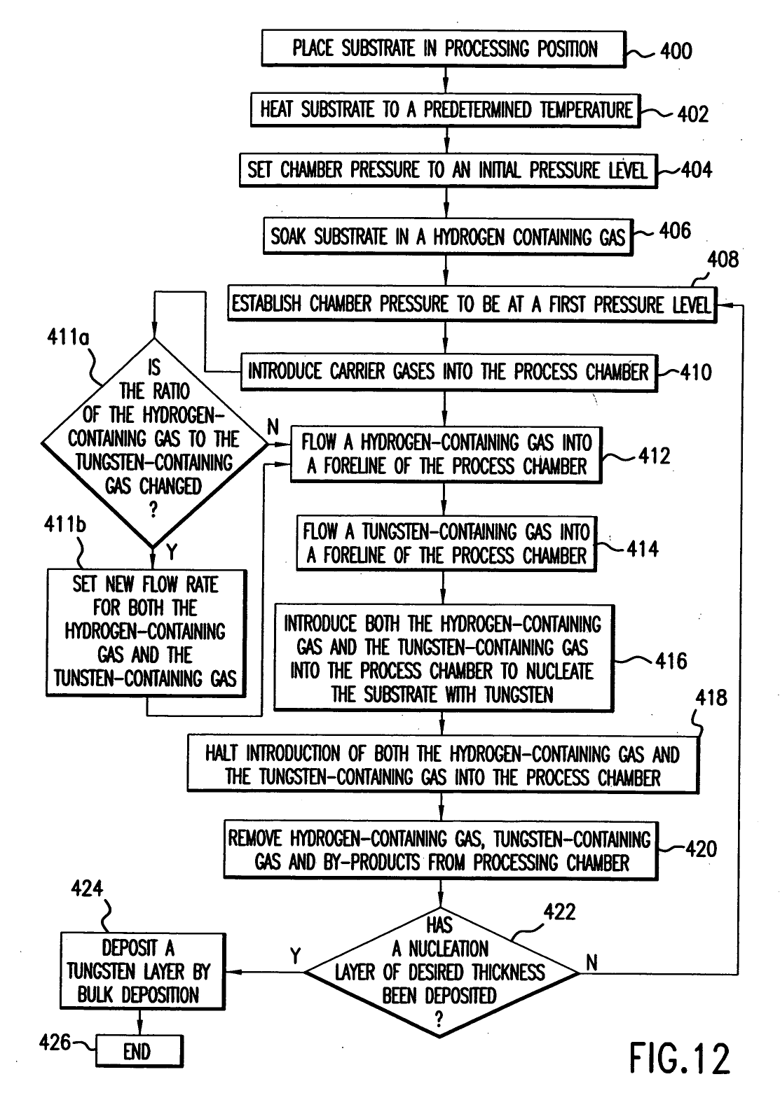

To that end, the process, shown in FIG. 12, includes steps 400, 402, 404, 406, 408, 410, 412, 414, 416, 418, 420, 422, 424 and 426 that are identical to steps 300, 302, 304, 306, 308, 310, 312, 314, 316, 318, 320, 322, 324 and 326, respectively, as shown in FIG. 11. Additional steps 411a and 411b are included in the process shown in FIG. 12 to take into consideration a process in which the ratio the tungsten-containing gas to the hydrogen-containing gas may have changed.

Referring to both FIGS. 1 and 12, step 411a occurs after step 410. At step 411a, processor 42 determines whether the ratio of the tungsten-containing gas to the hydrogen-containing gas has changed. If the ratio has not changed, the flow of the hydrogen-containing gas is resumed at step 412. Were the ratio changed, then step 411b would occur, in which a new flow rate for both the hydrogen-containing gas and the tungsten-containing gas would be set. Thereafter, step 412 would occur and the remaining steps would occur as discussed above, with respect to FIG. 11.

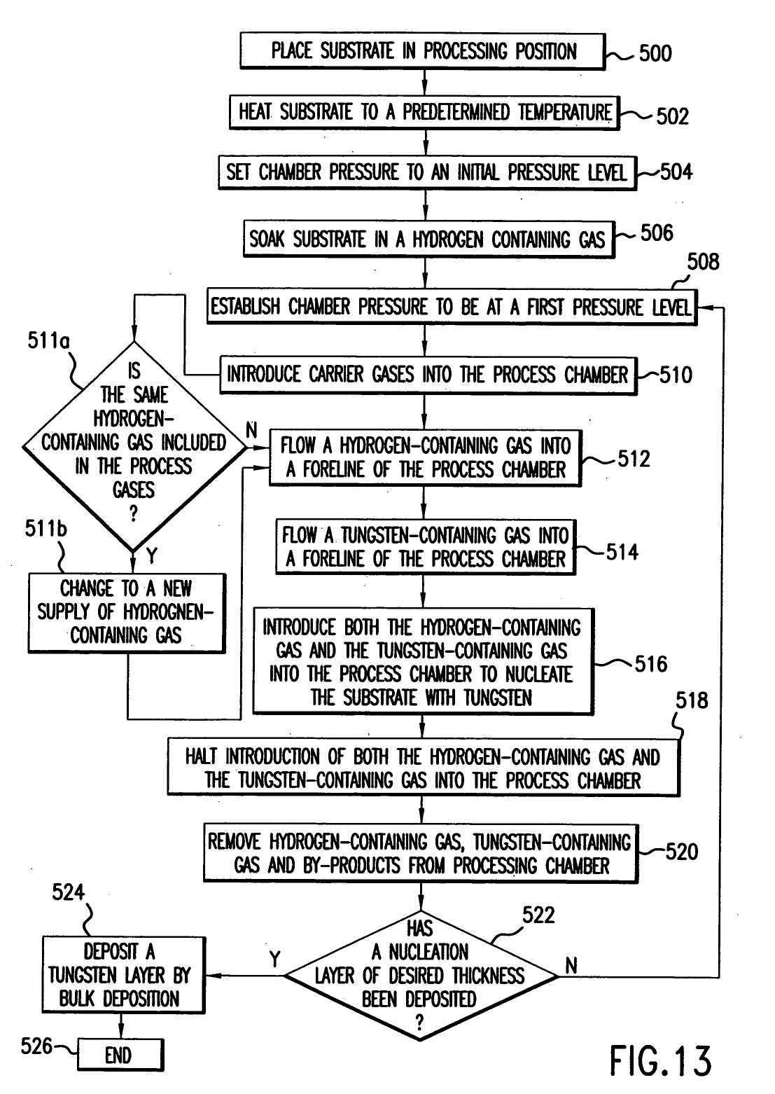

Referring to FIG. 13, shown is another alternate process for forming a tungsten layer that reduces the incubation time during soak step 506. Specifically, use of SiH₄ during the initial nucleation reduces the incubation time, reducing the time required to complete nucleation. However, molecular hydrogen, H₂, provides better step coverage than SiH₄. As a result, it may be beneficial to initiate nucleation with SiH₄ as a hydrogen-containing precursor and complete nucleation with molecular hydrogen, H₂.

To that end, the process shown in FIG. 13 includes steps 500, 502, 504, 506, 508, 510, 512, 514, 516, 518, 520, 522, 524 and 526 that are identical to steps 300, 302, 304, 306, 308, 310, 312, 314, 316, 318, 320, 322, 324 and 326, respectively, which are shown in FIG. 11. Additional steps 511a and 511b, are included in the process shown in FIG. 13 to take into consideration a process in which the hydrogen-containing precursor changes.

Referring to both FIGS. 1 and 13, step 511a occurs after step 510. At step 511a, processor 42 determines whether the same hydrogen-containing gas will be employed as was employed during an earlier nucleation process. If the type of hydrogen-containing gas has not changed, then the flow of the hydrogen-containing gas is resumed at step 512. Were the type of hydrogen-containing gas changed, then step 511bwould occur, in which a new supply of hydrogen-containing gas would be employed. Thereafter, step 512 would occur and the remaining steps would occur as discussed above with respect to FIG. 11. In this manner, Silane, SiH₄, may be employed during initial cycles of nucleation and molecular hydrogen, H₂, may be employed during subsequent nucleation cycles.

As stated above, processor 42 controls the operation of system 10 in accordance with the present invention. To that end, processor 42 may contain a single-board computer (SBC), analog and digital input/output boards, interface boards and stepper motor controller boards. Memory 46 may be any type known in the art, including a hard disk drive, a floppy disk drive, a RAID device, random access memory (RAM), read only memory (ROM) and the like. Various parts of CVD system 10 conform to the Versa Modular European (VME) standard which defines board, card cage, and connector dimensions and types. The VME standard also defines the bus structure as having a 16-bit data bus and a 24-bit address bus.

The computer program may be written in any conventional computer readable programming language: for example, 68000 assembly language, C, C++, Pascal, Fortran or others. Suitable programming language is entered into a single file, or multiple files, using a conventional text editor, and stored or embodied in a computer usable medium, such as memory 46. If the entered language is high level, then the same is compiled; and the resultant compiler code is linked with an object code of precompiled Windows® library routines. To execute the linked and compiled object code, a system user invokes the object code, causing the processor 42 to load the code in memory 46. Processor 42 then reads and executes the code to perform the tasks identified therein.

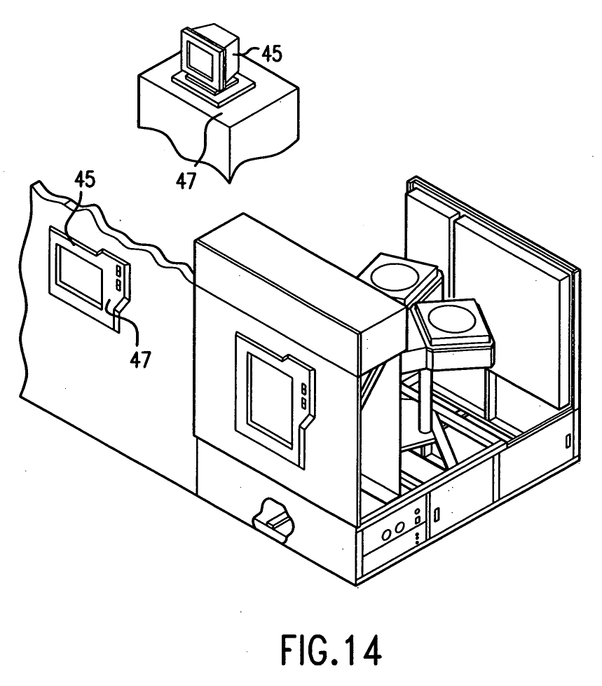

The interface between a user and processor 42 is via a CRT monitor 45 and light pen 47, shown in FIG. 14. The embodiment shown includes two monitors 45, one mounted in the clean room wall for the operators and the other behind the wall for the service technicians. Monitors 45 may simultaneously display the same information, with only one light pen 47 is enabled. A w light sensor in the tip of light pen 47 detects light emitted by a CRT display screen associated with the monitor 45. To select a particular screen or function, the operator touches a designated area of the display If screen and pushes the button on the pen 47. The touched area changes its highlighted color, or a new menu or screen is displayed, confirming communication between the light pen and the display screen. Other devices, such as a keyboard, mouse, or other pointing or communication devices may be used instead of, or in addition to, light pen 47 to allow the user to communicate with controller 42.

Referring to FIGS. 1, 14 and 15, shown is an illustrative block diagram of the hierarchical control structure of a computer program 70 that is stored in memory 46 is shown. Using the light pen interface, a user enters a process set number and processing chamber number into a process selector subroutine 73 in response to menus or screens displayed on the CRT monitor. The process sets are the predetermined sets of process parameters necessary to carry out specified processes, and are identified by predefined set numbers. The process selector subroutine 73 identifies (i) the desired processing chamber and (ii) the desired set of process parameters needed to operate the processing chamber for performing the desired process. The process parameters for performing a specific process relate to process conditions, e.g., process gas composition and flow rates, temperature, pressure, plasma conditions such as RF power levels and the low frequency RF frequency, cooling gas pressure, and chamber wall temperature. These parameters are provided to the user in the form of a recipe, and are entered utilizing the light pen/ monitor 45 and 47 interface.

The signals for monitoring the process are provided by the analog and digital input boards of the system controller, and the signals for controlling the process propagate on the analog and digital output boards of CVD system 10. A process sequencer subroutine 75 comprises program code for accepting the identified processing chamber and set of process parameters from the process selector subroutine 73, and for controlling operation of the various processing chambers. Multiple users can enter process set numbers and processing chamber numbers or a user can enter multiple process set numbers and processing chamber numbers, so the sequencer subroutine 75 operates to schedule the selected processes in the desired sequence. Preferably, the sequencer subroutine 75 includes a program code to perform the steps of (i) monitoring the operation of the processing chambers to determine if the chambers are being used, (ii) determining what processes are being carried out in the chambers being used, and (iii) executing the desired process based on availability of a processing chamber and type of process to be carried out. Conventional methods of monitoring the processing chambers can be used, such as polling. When scheduling the process to be executed, sequencer subroutine 75 takes into consideration the present condition of the processing chamber, as well as other relevant factors.

Once the sequencer subroutine 75 determines which processing chamber and process set combination is going to be executed next, the sequencer subroutine 75 initiates execution of the process set by passing the particular process set parameters to a chamber manager subroutine 77a-c, which controls multiple processing tasks in a processing chamber 12 according to the process set determined by the sequencer subroutine 75. For example, the chamber manager subroutine 77a comprises program code for controlling sputtering and CVD process operations in the processing chamber 12. The chamber manager subroutine 77 also controls execution of various chamber component subroutines that control operation of the chamber components necessary to carry out the selected process set. Examples of chamber component subroutines are substrate positioning subroutine 80, process gas control subroutine 83, pressure control subroutine 85, heater control subroutine 87 and plasma control subroutine 90, in some embodiments.

In operation, the chamber manager subroutine 77a selectively schedules or calls the process component subroutines, in accordance with the particular process set being executed. The chamber manager subroutine 77a schedules the process component subroutines in a similar manner to the way in which the sequencer subroutine 75 schedules which processing chamber 12 and process set are to be executed next. Typically, the chamber manager subroutine 77a includes steps of monitoring the various chamber components, determining which components need to be operated based on the process parameters for the process set to be executed, and causing execution of a chamber component subroutine responsive to the monitoring and determining steps.

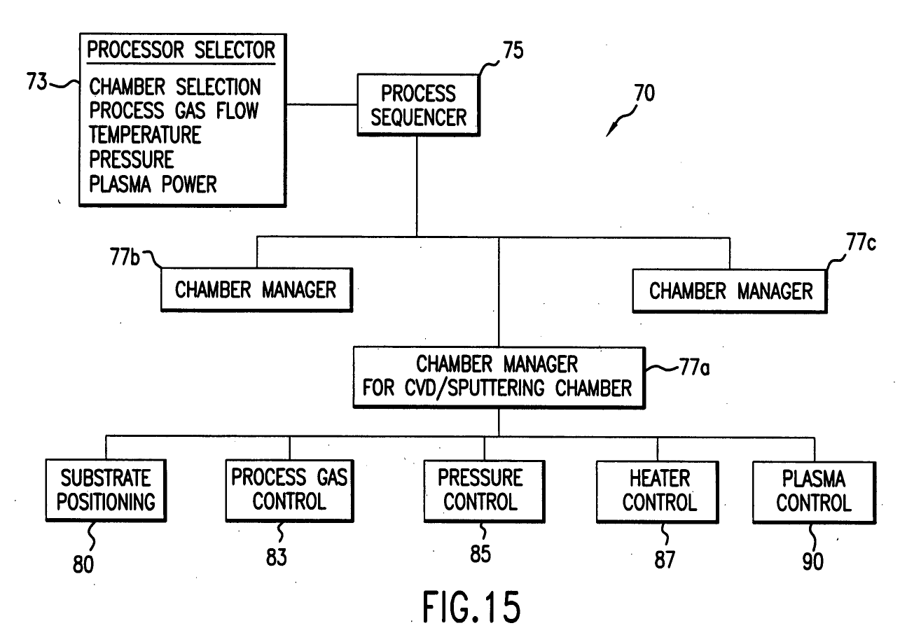

Referring to both FIGS. 1 and 15, substrate-positioning subroutine 80 comprises program code for controlling chamber components that are used to load the substrate onto susceptor 18. Optionally, substrate-positioning subroutine 80 may position substrate 16 within processing chamber 12, thereby controlling the distance between substrate 16 and gas distribution manifold 14. When substrate 16 is loaded into the processing chamber 12, susceptor 18 is lowered to receive the substrate, and thereafter, the susceptor 18 is raised to the desired height in processing chamber 12. In this manner, substrate 16 is maintained a first distance or spacing from the gas distribution manifold 14, during a deposition process. Substrate positioning subroutine 80 controls movement of susceptor 18, in response to process set parameters related to the support height, which are transferred from the chamber manager subroutine 77a.

Process gas control subroutine 83 has program code for controlling process gas composition and flow rates. Process gas control subroutine 83 controls the open/close position of the safety shut-off valves, and also ramps up/down the mass flow controllers to obtain the desired gas flow rate. Process gas control subroutine 83 is invoked by chamber manager subroutine 77a, as are all chamber component subroutines, and receives process parameters related to the desired gas flow rates from the chamber manager subroutine 77a. Typically, process gas control subroutine 83 operates by opening the gas supply lines and repeatedly (i) reading the necessary mass flow controllers, (ii) comparing the readings to the desired flow rates received from the chamber manager subroutine 77a, and (iii) adjusting the flow rates of the gas supply lines as necessary. Furthermore, process gas control subroutine 83 includes steps for monitoring the gas flow rates for unsafe rates and for activating the safety shut-off valves when an unsafe condition is detected.

In some processes, an inert gas such as helium, He, or argon, Ar, is flowed into processing chamber 12 to stabilize the chamber pressure before reactive process gases are introduced. For these processes, process gas control subroutine 83 is programmed to include steps for flowing the inert gas into processing chamber 12 for an amount of time necessary to stabilize the pressure in the chamber. Then, the steps described above are carried out.

Pressure control subroutine 85 comprises program code for controlling the chamber pressure by regulating the size of the opening of the throttle valve (not shown) in the exhaust system (not shown) of processing chamber 12. The size of the opening of the throttle valve (not shown) is set to control the chamber pressure to the desired level, in relation to, the total process gas flow, size of the processing chamber, and pumping setpoint pressure for the exhaust system. When pressure control subroutine 85 is invoked, the target level is received as a parameter from chamber manager subroutine 77a. Pressure control subroutine 85 operates to measure the chamber pressure by reading one or more conventional pressure manometers connected to the chamber in order to compare the measure value(s) to the target pressure, to obtain PID (proportional, integral, and differential) values from a stored pressure table corresponding to the target pressure, and to adjust the throttle valve accordingly. Alternatively, pressure control subroutine 85 may adjust the throttle valve (not shown) to regulate the chamber pressure.

Heater control subroutine 87 comprises program code for controlling the current to a heating unit that is used to heat the substrate 16. Heater control subroutine 87 is also invoked by chamber manager subroutine 77a and receives a target, or set-point, temperature parameter. Heater control subroutine 87 measures the temperature by measuring the voltage output of a thermocouple located in pedestal 18. Heater control subroutine 87 also compares the measured temperature to the set-point temperature, and increases or decreases current applied to the heating unit to obtain the set-point temperature. The temperature is obtained from the measured voltage by looking up the corresponding temperature in a stored conversion table, or by calculating the temperature using a fourth-order polynomial. Were an embedded loop used to heat susceptor 18, heater control subroutine 87 would gradually control a ramp up/down of current applied to the loop. Additionally, a built-in fail-safe mode could be included to detect process safety compliance, and could shut down operation of the heating unit if the processing chamber 12 were not properly set up.

In some embodiments, processing chamber 12 is outfitted with an RF power supply 48 that is used for chamber cleaning or other operations. Were a chamber cleaning plasma process employed, plasma control subroutine 90 would comprise program code for setting the frequency RF power levels applied to the process electrodes in the chamber 12. Similarly to the previously described chamber component subroutines, plasma control subroutine 90 would be invoked by chamber manager subroutine 77a.

The process parameters set forth above are exemplary, as are the process gases recited above. It should be understood that the processing conditions might be varied as desired. For example, the invention has been described as depositing a tungsten layer adjacent to a layer of TiN. However, the present process works equally well when depositing a tungsten layer adjacent to a layer of titanium, Ti, or directly upon a wafer surface. Other layers in addition, metal layers, may also be nucleated employing the present processes. Therefore, the scope of the invention should be determined not with reference to the above description, but instead should be determined with reference to the appended claims along with their full scope of equivalents.

What is claimed is:

1. A process for depositing a metal film on a substrate disposed in a processing chamber, said process comprising:
heating said substrate; and
introducing into, and removing from, said processing chamber, a process gas consisting of a metal source and a hydrogen source to nucleate said substrate with metal while controlling production of a concentration boundary layer by rapidly removing said process gas from said processing chamber after commencement of nucleation of said substrate.

2. The process as recited in claim 1 wherein introducing and removing occurs multiple times to nucleate said substrate with a layer of metal of a desired thickness.

3. The process as recited in claim 1 wherein introducing and removing further includes pressurizing said processing chamber to a first pressure level upon introduction of said process gas and pressurizing said processing chamber to a second pressure level upon removing said process gas, with said first pressure level being greater than said second pressure level.

4. The process as recited in claim 1 wherein introducing and removing further includes introducing a purge gas into said processing chamber to remove said process gas from said processing chamber.

5. The process as recited in claim 1 wherein introducing and removing further includes introducing a purge gas into said processing chamber to remove said process gas while maintaining a pressurization of said processing chamber at a constant level.

6. The process as recited in claim 1 wherein introducing and removing further includes introducing a purge gas into said processing chamber while decreasing a pressurization of said processing chamber.

7. The process as recited in claim 2 wherein introducing said process gas occurs for approximately 3 to five seconds and further including terminating removing said process gas after approximately 7-12 seconds and before repeating systematically introducing into, and removing from, said processing chamber.

8. The process as recited in claim 1 wherein introducing into, and removing from, said processing chamber, defines a nucleation cycle and further including repeating said nucleation cycle multiple times, defining a sequence of nucleation cycles, to form a metal nucleation layer upon said substrate, and varying a ratio of said metal source with respect to said hydrogen source during successive nucleation cycles in said sequence.

9. The process as recited in claim 1 further including forming, after introducing into, and removing from, said processing chamber, a bulk deposition layer of metal.

10. The process as recited in claim 1 wherein said first pressurization is approximately 15 Torr and said second pressurization is in the range of 1 to 3 Torr.

11. The process as recited in claim 1 wherein said metal source is tungsten hexafluoride, WF₆ and said hydrogen source is selected from a group consisting of silane, SiH₄ molecular hydrogen, H₂, and diborane, B₂H₆.

12. The process as recited in claim 1 further including establishing an initial pressurization in said processing chamber, before introducing into, and removing from, said processing chamber, said process gas, with said initial pressurization being greater than said first pressurization.

13. The process as recited in claim 12 wherein establishing said initial pressurization further includes introducing said hydrogen source while establishing said initial pressurization.

14. A process for depositing a metal film on a substrate disposed in a processing chamber, said process comprising:
heating said substrate; and
introducing into, and removing from, said processing chamber, a process gas consisting of a tungsten source and a hydrogen source to nucleate said substrate with tungsten by rapidly removing said process gas from said processing chamber after commencement of nucleation of said substrate with tungsten.

15. The process as recited in claim 14 wherein introducing and removing occurs multiple times to nucleate said substrate with a layer of tungsten of a desired thickness.

16. The process as-recited in claim 15 further including forming, after nucleation of said substrate with a layer of tungsten of a desired thickness, a bulk deposition layer of tungsten.

17. The process as recited in claim 16 wherein said tungsten source in tungsten hexafluoride, WF₆ and said hydrogen source being selected from a group consisting of silane, SiH₄, molecular hydrogen, H₂, and diborane, B₂H₆.

18. The process as recited in claim 17 further including establishing an initial pressurization in said processing chamber, before introducing into, and removing from, said processing chamber, said process gas, with said initial pressurization being greater than said first pressurization.

19. The process as recited in claim 18 wherein establishing said initial pressurization further includes introducing said hydrogen source while establishing said initial pressurization.

20. The process as recited in claim 19 wherein introducing and removing further includes pressurizing said processing chamber to a first pressure level upon introduction of said process gas and pressurizing said processing chamber to a second pressure level upon removing said process gas, with said first pressure level being greater than said second pressure level.

21. The process as recited in claim 19 wherein introducing and removing further includes introducing a purge gas into said processing chamber to remove said process gas from said processing chamber.

22. The process as recited in claim 19 wherein introducing and removing further includes introducing a purge gas into said processing chamber to remove said process gas while maintaining a pressurization of said processing chamber at a constant level.

23. The process as recited in claim 19 wherein introducing and removing further includes introducing a purge gas into said processing chamber while decreasing a pressurization of said processing chamber.

24. The process as recited in claim 19 further including repeating nucleating tungsten onto said substrate multiple times to form a nucleation layer tungsten upon said substrate, defining a sequence of nucleation cycles, and varying a ratio of said tungsten source with respect to said hydrogen source during successive nucleation cycles in said sequence.

25. A deposition system for depositing a metal film on a substrate disposed in a processing chamber, said process comprising:
means, in thermal communication with said processing chamber, for heating said substrate; and
means, in fluid communication with said processing chamber, for introducing into, and removing from, said processing chamber, a process gas consisting of a tungsten source and a hydrogen source to nucleate said substrate with tungsten while controlling production of a concentration boundary layer by rapidly removing said process gas from said processing chamber after commencement of nucleation of said substrate.

26. A processing system for a substrate, said system comprising:
a body defining a processing chamber;
a holder, disposed within said processing chamber, to support said substrate;
a gas delivery system in fluid communication with said processing chamber;
a temperature control system in thermal communication with said processing chamber;
a pressure control system in fluid communication with said processing chamber, said pressure control system including a pump having a throttle valve;
a controller in electrical communication with said gas delivery system, said temperature control system, and said pressure control system; and
a memory in data communication with said controller, said memory comprising a computer-readable medium having a computer-readable program embodied therein, said computer-readable program including a first set of instructions for controlling said temperature control system to heat said substrate, and a second set of instructions to control said gas delivery system and said pressure control system to nucleate tungsten onto said substrate by introducing into, and removing from, said processing chamber, a process gas consisting of a tungsten source and a hydrogen source to nucleate said substrate with tungsten while controlling production of a concentration boundary layer by rapidly removing said process gas from said processing chamber after commencement of nucleation of said substrate.

27. The processing system as recited in claim 25 wherein said computer-readable program further including a third set of instructions to control said gas delivery system and said pressure control system to repeat nucleating tungsten onto said substrate multiple times to form a nucleation layer of tungsten, and a fourth set of instructions to control said pressure control system, sand temperature control system and said gas delivery system to deposit a bulk deposition layer of tungsten adjacent to said nucleation layer.

28. The processing system as recited in claim 26 wherein said computer-readable program includes a third set of instructions to control said gas delivery system and said pressure control system to repeat nucleating tungsten onto said substrate multiple times to form a nucleation layer tungsten, defining a sequence of nucleation cycles, and varying a ratio of said tungsten source with respect to said hydrogen source during successive nucleation cycles in said sequence.

29. The system as recited in claim 26 said wherein said second set of instructions further includes a subroutine to cause said gas delivery system to introduce said process gas occurs for approximately 3-7 seconds and repeat introducing said process gas to nucleate tungsten onto said substrate 7 to 12 seconds after removing said process gas commences.

30. The system as recited in claim 28 wherein said tungsten source is tungsten hexafluoride, WF₆, and said hydrogen source being selected from a group consisting of silane, SiH₄, molecular hydrogen, H₂, and diborane, B₂H₆.
